(19) United States
(12) Patent Application Publication
(10) Pub. No.: US 2013/0192670 A1
(43) Pub. Date: Aug. 1, 2013

(54) ALUMINUM PASTE AND USE THEREOF IN THE PRODUCTION OF PASSIVATED EMITTER AND REAR CONTACT SILICON SOLAR CELLS

(71) Applicants: KENNETH WARREN HANG, Cary, NC (US); GIOVANNA LAUDISIO, Bristol (GB); ALISTAIR GRAEME PRINCE, Bedminster (GB); YUELI WANG, Cary, NC (US); ROSALYNNE SOPHIE WATT, Bristol (GB)

(72) Inventors: KENNETH WARREN HANG, Cary, NC (US); GIOVANNA LAUDISIO, Bristol (GB); ALISTAIR GRAEME PRINCE, Bedminster (GB); YUELI WANG, Cary, NC (US); ROSALYNNE SOPHIE WATT, Bristol (GB)

(73) Assignee: E I DU PONT DE NEMOURS AND COMPANY, Wilmington, DE (US)

(21) Appl. No.: 13/565,909

(22) Filed: Aug. 3, 2012

Related U.S. Application Data
(60) Provisional application No. 61/522,364, filed on Aug. 11, 2011.

(51) Int. Cl. H01L 31/0224

(52) U.S. Cl. CPC H01L 31/022425
USPC 136/256; 438/98; 252/512

(57) ABSTRACT

An aluminum paste having no or only poor fire-through capability and comprising particulate aluminum, an organic vehicle and at least one glass frit selected from the group consisting of lead-free glass frits containing 0.5 to 15 wt. % SiO₂, 0.3 to 10 wt. % Al₂O₃ and 67 to 75 wt. % Bi₂O₃, and the use of such aluminum paste in the manufacture of aluminum back anodes of PERC silicon solar cells.

### FIELD OF THE INVENTION

The invention is directed to an aluminum paste and its use in the production of PERC (passivated emitter and rear contact) silicon solar cells, i.e., in the production of aluminum back electrodes of silicon solar cells of the PERC cell type and the respective silicon solar cells.

### TECHNICAL BACKGROUND OF THE INVENTION

Typically, silicon solar cells have both front- and back-side metallizations (front and back electrodes). A conventional silicon solar cell structure with a p-type base uses a negative electrode to contact the front-side or illuminated side of the cell, and a positive electrode on the back-side. It is well known that radiation of an appropriate wavelength falling on a p-n junction of a semiconductor body serves as a source of external energy to generate electron-hole pairs in that body. The potential difference that exists at a p-n junction, causes holes and electrons to move across the junction in opposite directions, thereby giving rise to flow of an electric current that is capable of delivering power to an external circuit. Most solar cells are in the form of a silicon wafer that has been metallized, i.e., provided with metal contacts which are electrically conductive.

The majority of the solar cells currently produced are based upon crystalline silicon. A popular method for depositing electrodes is the screen printing of metal pastes.

US2011/120535A1 discloses aluminum thick film compositions having no or only poor fire-through capability. The aluminum thick film compositions comprise particulate aluminum, an organic vehicle and at least one glass frit selected from the group consisting of (i) lead-free glass frits with a softening point temperature in the range of 550 to 611° C. and containing 11 to 33 wt. % (weight-%) of SiO₂, >0 to 7 wt. % of Al₂O₃ and 2 to 10 wt. % of B₂O₃ and (ii) lead-containing glass frits with a softening point temperature in the range of 571 to 636° C. and containing 53 to 57 wt. % of PbO, 25 to 29 wt. % of SiO₂, 2 to 6 wt. % of Al₂O₃ and 6 to 9 wt. % of B₂O₃. The aluminum thick film compositions can be used for forming aluminum back electrodes of PERC silicon solar cells.

### SUMMARY OF THE INVENTION

The invention relates to an aluminum paste (aluminum thick film composition) that can be used for forming aluminum back electrodes of PERC silicon solar cells. It further relates to the process of forming and use of the aluminum paste in the production of PERC silicon solar cells and the PERC silicon solar cells themselves.

The invention is directed to an aluminum paste having no or only poor fire-through capability and including particulate aluminum, an organic vehicle and at least one lead-free glass frit selected from the group consisting of glass frits containing 0.5 to 15 wt. % SiO₂, 0.3 to 10 wt. % Al₂O₃ and 67 to 75 wt. % Bi₂O₃, wherein the weight percentages are based on the total weight of the glass frit.

The invention is further directed to a process of forming a PERC silicon solar cell and the PERC silicon solar cell itself which utilizes a silicon wafer having a p-type and an n-type region, a p-n junction, a front-side ARC (antireflective coating) layer and a back-side perforated dielectric passivation layer, which includes applying, for example printing, in particular screen-printing, an aluminum paste of the invention on the back-side perforated dielectric passivation layer, and firing the aluminum paste so applied, whereby the wafer reaches a peak temperature in the range of 700 to 900° C.

The invention is also directed to a process of forming an LFC-PERC (laser-fired contact PERC) silicon solar cell and the LFC-PERC silicon solar cell itself which utilizes a silicon wafer having a p-type and an n-type region, a p-n junction, a front-side ARC layer and a back-side non-perforated dielectric passivation layer, which includes applying, for example printing, in particular screen-printing, an aluminum paste of the invention on the back-side dielectric passivation layer, firing the aluminum paste so applied, whereby the wafer reaches a peak temperature in the range of 700 to 900° C., and then laser firing the fired aluminum layer to produce perforations in the dielectric passivation layer and to form local BSF contacts.

### DETAILED DESCRIPTION OF THE INVENTION

In the present description and the claims the term “fire-through capability” is used. It shall mean the ability of a metal paste to etch and penetrate through (fire through) a passivation or ARC layer during firing. In other words, a metal paste with fire-through capability is one that fires through a passivation or an ARC layer making electrical contact with the surface of the silicon substrate beneath. Correspondingly, a metal paste with poor or even no fire through capability makes no electrical contact with the silicon substrate upon firing. To avoid misunderstandings; in this context the term “no electrical contact” shall not be understood absolute; rather, it shall mean that the contact resistivity between fired metal paste and silicon surface exceeds 1 Ω·cm², whereas, in case of electrical contact, the contact resistivity between fired metal paste and silicon surface is in the range of 1 to 10 Ω·cm².

The contact resistivity can be measured by TLM (transfer length method). To this end, the following procedure of sample preparation and measurement may be used: A silicon wafer having a non-perforated back-side passivation layer is screen printed on the passivation layer with the aluminum paste to be tested in a pattern of parallel 100 μm wide and 20 μm thick lines with a spacing of 2.05 mm between the lines and is then fired with the wafer reaching a peak temperature of 730° C. It is preferred for the sample preparation to use a silicon wafer with the same type of back-side passivation layer as is used in the process of the invention, i.e. in the process of forming PERC silicon solar cells making use of the aluminum paste of the invention. The fired wafer is laser-cutted into 8 mm by 42 mm long strips, where the parallel lines do not touch each other and at least 6 lines are included. The strips are then subject to conventional TLM measurement at 20° C. in the dark. The TLM measurement can be carried out using the device GP 4-Test Pro from GP Solar.

PERC silicon solar cells are well-known to the skilled person; see, for example, P. Choulat et al., “Above 17% industrial type PERC Solar Cell on thin Multi-Crystalline Silicon Substrate”, 22nd European Photovoltaic Solar Energy Conference, 3-7 Sep. 2007, Milan, Italy. PERC silicon solar cells represent a special type of conventional silicon solar cells; they are distinguished by having a dielectric passivation layer on their front- and on their back-side. The passivation layer on the front-side serves as an ARC (antireflective coating) layer, as is conventional for silicon solar cells. The dielectric passivation layer on the back-side is perforated; it serves to extend charge carrier lifetime and as a result thereof improves light conversion efficiency. It is desired to avoid damage of the perforated dielectric back-side passivation layer as much as possible.

Similar to the production of a conventional silicon solar cell, the production of a PERC silicon solar cell typically starts with a p-type silicon substrate in the form of a silicon wafer on which an n-type diffusion layer (n-type emitter) of the reverse conductivity type is formed by the thermal diffusion of phosphorus (P) or the like. Phosphorus oxychloride (POCl3) is commonly used as the gaseous phosphorus diffusion source, other liquid sources are phosphoric acid and the like. In the absence of any particular modification, the n-type diffusion layer is formed over the entire surface of the silicon substrate. The p-n junction is formed where the concentration of the p-type dopant equals the concentration of the n-type dopant. The cells having the p-n junction close to the illuminated side, have a junction depth between 0.05 and 0.5 μm.

After formation of this diffusion layer excess surface glass is removed from the rest of the surfaces by etching by an acid such as hydrofluoric acid.

Next, a dielectric layer, for example, of TiOx, SiOx, TiOx/SiOx, SiNx or, in particular, a dielectric stack of SiNx/SiOx is formed on the front-side n-type diffusion layer. As a specific feature of the PERC silicon solar cell, the dielectric is also deposited on the back-side of the silicon wafer to a thickness of, for example, between 0.05 and 0.1 μm. Deposition of the dielectric may be performed, for example, using a process such as plasma CVD (chemical vapor deposition) in the presence of hydrogen or sputtering. Such a layer serves as both an ARC and passivation layer for the front-side and as a dielectric passivation layer for the back-side of the PERC silicon solar cell. The passivation layer on the back-side of the PERC silicon solar cell is then perforated. The perforations are typically produced by acid etching or laser drilling and the holes so produced are, for example, 50 to 300 μm in diameter. Their depth corresponds to the thickness of the passivation layer or may even slightly exceed it. The number of the perforations lies in the range of, for example, 100 to 500 per square centimeter.

Just like a conventional solar cell structure with a p-type base and a front-side n-type emitter, PERC silicon solar cells typically have a negative electrode on their front-side and a positive electrode on their back-side. The negative electrode is typically applied as a grid by screen printing and drying a front-side silver paste (front electrode forming silver paste) on the ARC layer on the front-side of the cell. The front-side grid electrode is typically screen printed in a so-called H pattern which comprises thin parallel finger lines (collector lines) and two busbars intersecting the finger lines at right angle. In addition, a back-side silver or silver/aluminum paste and an aluminum paste are applied, typically screen printed, and successively dried on the perforated passivation layer on the back-side of the p-type silicon substrate. Normally, the back-side silver or silver/aluminum paste is applied onto the back-side perforated passivation layer first to form anodic back contacts, for example, as two parallel busbars or as rectangles or tabs ready for soldering interconnection strings (presoldered copper ribbons). The aluminum paste is then applied in the bare areas with a slight overlap over the back-side silver or silver/aluminum. In some cases, the silver or silver/aluminum paste is applied after the aluminum paste has been applied. Firing is then typically carried out in a belt furnace for a period of 1 to 5 minutes with the wafer reaching a peak temperature in the range of 700 to 900° C. The front electrode and the back electrodes can be fired sequentially or cofired.

The aluminum paste is generally screen printed and dried on the perforated dielectric passivation layer on the back-side of the silicon wafer. The wafer is fired at a temperature above the melting point of aluminum to form an aluminum-silicon melt at the local contacts between the aluminum and the silicon, i.e. at those parts of the silicon wafer's back-surface not covered by the dielectric passivation layer or, in other words, at the places of the perforations. The so-formed local p+ contacts are generally called local BSF (back surface field) contacts. The aluminum paste is transformed by firing from a dried state to an aluminum back electrode, whereas the back-side silver or silver/aluminum paste becomes a silver or silver/aluminum back electrode upon firing. Typically, aluminum paste and back-side silver or silver/aluminum paste are cofired, although sequential firing is also possible. During firing, the boundary between the back-side aluminum and the back-side silver or silver/aluminum assumes an alloy state, and is connected electrically as well. The aluminum electrode accounts for most areas of the back electrode. A silver or silver/aluminum back electrode is formed over portions of the back-side as an anode for interconnecting solar cells by means of pre-soldered copper ribbon or the like. In addition, the front-side silver paste printed as front-side cathode etches and penetrates through the ARC layer during firing, and is thereby able to electrically contact the n-type layer. This type of process is generally called “firing through”.

A slightly deviating process for the manufacture of the back electrode of a PERC silicon solar cell is also known. Here, the aluminum electrode accounts for the entire area of the back electrode and the silver or silver/aluminum back electrode takes the form of a silver back electrode pattern connecting the local BSF contacts. This means, the aluminum paste is applied full plane and fired to form local BSF contacts and the silver or silver/aluminum back electrode is applied taking the form of a silver or silver/aluminum back electrode pattern connecting the local BSF contacts. “Silver or silver/aluminum back electrode pattern” shall mean the arrangement of a silver or silver/aluminum back anode as a pattern of fine lines connecting all local BSF contacts. Examples include an arrangement of parallel but connected fine lines connecting all local BSF contacts or a grid of fine lines connecting all local BSF contacts. In case of such grid, it is typically, but not necessarily, a checkered grid. Main point is that the silver back electrode pattern is a pattern which connects all local BSF contacts and thus also guarantees electrical connection of the latter. The silver back electrode pattern is in electrical contact with one or more anodic back contacts ready for soldering interconnection strings like, for example, presoldered copper ribbons. The anodic back contact(s) may take the form of one or more busbars, rectangles or tabs, for example. The anodic back contact(s) itself/themselves may form part of the silver back electrode pattern and may simultaneously be applied together with the fine lines. It is also possible to apply the anodic back contacts separately, i.e. before or after application of the fine lines which connect all local BSF contacts.

A special embodiment of PERC silicon solar cells is also known. The local BSF contacts are here made by laser firing; we call such PERC silicon solar cells therefore LFC-PERC (laser-fired contact PERC) silicon solar cells. Here, the silicon wafer provided with front ARC layer and back-side passivation layer is not subject to the aforementioned acid etching or laser drilling step. Rather, the aluminum paste is applied on the non-perforated back-side passivation layer and fired without making contact with the silicon surface underneath the back-side passivation layer. Only thereafter a laser firing step is carried out during which not only the perforations but also the local BSF contacts are produced. The principle is disclosed in DE102006046726 A1 and US2004/097062 A1, for example.

The aluminum paste of the invention has no or only poor fire-through capability. Hence, it broadens the raw material basis with regard to aluminum pastes having no or only poor fire-through capability.

It has been found that the aluminum paste of the invention allows for the production of PERC silicon solar cells with improved electrical efficiency. The fired aluminum paste adheres well to the back-side passivation layer and thus gives rise to a long durability or service life of the PERC silicon solar cells produced with the aluminum paste.

While not wishing to be bound by any theory it is believed that the aluminum paste of the invention does not or not significantly damage the dielectric passivation layer on the silicon wafer's back-side and/or exhibits no or only reduced escaping of aluminum-silicon alloy through the perforations in the silicon wafer's back-side passivation layer during firing or laser firing.

The aluminum paste of the invention includes particulate aluminum, an organic vehicle and at least one lead-free glass frit selected from the group consisting of glass frits containing 0.5 to 15 wt. % SiO₂, 0.3 to 10 wt. % Al₂O₃ and 67 to 75 wt. % Bi₂O₃.

The particulate aluminum may be aluminum or an aluminum alloy with one or more other metals like, for example, zinc, tin, silver and magnesium. In case of aluminum alloys the aluminum content is, for example, 99.7 to below 100 wt. %. The particulate aluminum may include aluminum particles in various shapes, for example, aluminum flakes, spherical-shaped aluminum powder, nodular-shaped (irregular-shaped) aluminum powder or any combinations thereof. In an embodiment, the particulate aluminum is aluminum powder. The aluminum powder exhibits an average particle size of, for example, 4 to 12 μm. The particulate aluminum may be present in the aluminum paste in a proportion of 50 to 80 wt. %, or, in an embodiment, 70 to 75 wt. %, based on total aluminum paste composition.

In the present description and the claims the term “average particle size” is used. It shall mean the average particle size (mean particle diameter, d50) determined by means of laser scattering.

All statements made in the present description and the claims in relation to average particle sizes relate to average particle sizes of the relevant materials as are present in the aluminum paste composition.

The particulate aluminum present in the aluminum paste may be accompanied by other particulate metal(s) such as, for example, silver or silver alloy powders. The proportion of such other particulate metal(s) is, for example, 0 to 10 wt. %, based on the total of particulate aluminum plus other particulate metal(s).

The aluminum paste includes an organic vehicle. A wide variety of inert viscous materials can be used as organic vehicle. The organic vehicle may be one in which the particulate constituents (particulate aluminum, optionally present other particulate metals, glass frit, further optionally present inorganic particulate constituents) are dispersible with an adequate degree of stability. The properties, in particular, the rheological properties, of the organic vehicle may be such that they lend good application properties to the aluminum paste composition, including: stable dispersion of insoluble solids, appropriate viscosity and thixotropy for application, in particular, for screen printing, appropriate wettability of the silicon wafer's back-side passivation layer and the paste solids, a good drying rate, and good firing properties. The organic vehicle used in the aluminum paste may be a nonaqueous inert liquid. The organic vehicle may be an organic solvent or an organic solvent mixture; in an embodiment, the organic vehicle may be a solution of organic polymer(s) in organic solvent(s). In an embodiment, the polymer used for this purpose may be ethyl cellulose. Other examples of polymers which may be used alone or in combination include ethylhydroxyethyl cellulose, wood rosin, phenolic resins and poly(meth)acrylates of lower alcohols. Examples of suitable organic solvents include ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after application of the aluminum paste on the back-side passivation layer can be included in the organic vehicle. Various combinations of these and other solvents may be formulated to obtain the viscosity and volatility requirements desired.

The organic vehicle content in the aluminum paste may be dependent on the method of applying the paste and the kind of organic vehicle used, and it can vary. In an embodiment, it may be from 20 to 45 wt. %, or, in an embodiment, it may be in the range of 22 to 35 wt. %, based on total aluminum paste composition. The number of 20 to 45 wt. % includes organic solvent(s), possible organic polymer(s) and possible organic additive(s).

The organic solvent content in the aluminum paste may be in the range of 5 to 25 wt. %, or, in an embodiment, 10 to 20 wt. %, based on total aluminum paste composition.

The organic polymer(s) may be present in the organic vehicle in a proportion in the range of 0 to 20 wt. %, or, in an embodiment, 5 to 10 wt. %, based on total aluminum paste composition.

The aluminum paste includes at least one lead-free glass frit as inorganic binder. The at least one lead-free glass frit is selected from the group consisting of glass frits containing 0.5 to 15 wt. % SiO₂, 0.3 to 10 wt. % Al₂O₃ and 67 to 75 wt. % Bi₂O₃. The weight percentages of SiO₂, Al₂O₃ and Bi₂O₃ may or may not total 100 wt. %. In case they do not total 100 wt. % the missing wt. % may in particular be contributed by one or more other constituents, for example, B₂O₃, ZnO, BaO, ZrO₂, P₂O₅, SnO₂ and/or BiF₃.

In an embodiment, the at least one lead-free glass frit includes 0.5 to 15 wt. % SiO₂, 0.3 to 10 wt. % Al₂O₃, 67 to 75 wt. % Bi₂O₃ and at least one of the following: >0 to 12 wt. % B₂O₃, >0 to 16 wt. % ZnO, >0 to 6 wt. % BaO. All weight percentages are based on the total weight of the glass frit.

Specific compositions for lead-free glass frits that can be used in the aluminum paste of the invention are shown in Table I. The table shows the wt. % of the various ingredients in glass frits A-N, based on the total weight of the glass frit.

TABLE I

| | SiO₂ | Al₂O₃ | ZrO₂ | B₂O₃ | ZnO | BaO | Bi₂O₃ | P₂O₅ | SnO₂ | BiF₃ |
|---|---|---|---|---|---|---|---|---|---|---|
| A | 3.00 | 3.00 | | 12.00 | 7.00 | 5.00 | 70.00 | | | |
| B | 5.00 | 5.00 | | 8.00 | 7.00 | 5.00 | 70.00 | | | |
| C | 6.00 | 3.00 | | 6.00 | 7.00 | 4.00 | 74.00 | | | |
| D | 2.60 | 0.85 | | 8.10 | 13.20 | 2.25 | 73.00 | | | |
| E | 1.50 | 3.00 | | 7.50 | 14.50 | 3.50 | 70.00 | | | |
| F | 1.00 | 0.50 | | 9.50 | 13.00 | 3.00 | 73.00 | | | |
| G | 1.00 | 0.50 | | 9.50 | 13.00 | 3.00 | 73.00 | | | |
| H | 1.90 | 0.60 | | 8.20 | 13.50 | 2.60 | 73.20 | | | |
| I | 10.49 | 1.94 | 1.14 | | | | 73.94 | 2.70 | | 9.80 |
| J | 11.88 | 6.19 | | 9.72 | | | 72.21 | | | |
| K | 1.00 | 0.50 | | 9.50 | 13.00 | 3.00 | 73.00 | | | |
| L | 7.50 | 2.90 | | 7.50 | 11.00 | 1.90 | 69.20 | | | |
| M | 2.00 | 0.80 | | 8.40 | 13.40 | 2.40 | 72.50 | | | 0.50 |
| N | 7.17 | 7.17 | | 8.50 | 7.16 | | 70.00 | | | |

Generally, the aluminum paste includes no glass frit other than the at least one lead-free glass frit.

The average particle size of the glass frit(s) may be in the range of, for example, 0.5 to 4 μm. The total content of the at least one lead-free glass frit in the aluminum paste is, for example, 0.25 to 8 wt. %, or, in an embodiment, 0.8 to 3.5 wt. %.

The preparation of the glass frits is well known and consists, for example, in melting together the constituents of the glass, in particular in the form of the oxides of the constituents, and pouring such molten composition into water to form the frit. As is well known in the art, heating may be conducted to a peak temperature in the range of, for example, 1050 to 1250° C. and for a time such that the melt becomes entirely liquid and homogeneous, typically, 0.5 to 1.5 hours.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well.

The aluminum paste may include refractory inorganic compounds and/or metal-organic compounds. “Refractory inorganic compounds” refers to inorganic compounds that are resistant to the thermal conditions experienced during firing. For example, they have melting points above the temperatures experienced during firing. Examples include solid inorganic oxides, for example, amorphous silicon dioxide. Examples of metal-organic compounds include tin- and zinc-organic compounds such as zinc neodecanoate and tin(II) 2-ethylhexanoate. In an embodiment, the aluminum paste is free from metal oxides and from compounds capable of generating such oxides on firing. In another embodiment, the aluminum paste is free from any refractory inorganic compounds and/or metal-organic compounds.

It may be advantageous for the aluminum paste to contain a small amount of at least one antimony oxide. Therefore, in an embodiment, the aluminum paste of the invention may comprise at least one antimony oxide. The at least one antimony oxide may be contained in the aluminum paste in a total proportion of, for example, 0.01 to 1.5 wt.-%, based on total aluminum paste composition, wherein the at least one antimony oxide may be present as separate particulate constituent(s) and/or as glass frit constituent(s). Examples of suitable antimony oxides include Sb₂O₃ and Sb₂O₅, wherein Sb₂O₃ is the preferred antimony oxide.

The aluminum paste may include one or more organic additives, for example, surfactants, thickeners, rheology modifiers and stabilizers. The organic additive(s) may be part of the organic vehicle. However, it is also possible to add the organic additive(s) separately when preparing the aluminum paste. The organic additive(s) may be present in the aluminum paste in a total proportion of, for example, 0 to 10 wt. %, based on total aluminum paste composition.

The aluminum paste is a viscous composition, which may be prepared by mechanically mixing the particulate aluminum and the glass frit(s) with the organic vehicle. In an embodiment, the manufacturing method power mixing, a dispersion technique that is equivalent to the traditional roll milling, may be used; roll milling or other mixing technique can also be used.

The aluminum paste can be used as such or may be diluted, for example, by the addition of additional organic solvent(s); accordingly, the weight percentage of all the other constituents of the aluminum paste may be decreased.

The aluminum paste of the invention may be used in the manufacture of aluminum back electrodes of PERC silicon solar cells (conventional PERC silicon solar cells as well as LFC-PERC silicon solar cells as representatives of a special embodiment of PERC silicon solar cells). Respectively, the aluminum paste may be used in the manufacture of PERC silicon solar cells.

The manufacture may be performed by applying the aluminum paste to the back-side of a silicon wafers provided with a front-side ARC layer and a back-side perforated dielectric passivation layer. After application of the aluminum paste it is fired to form an aluminum back electrode.

Accordingly, the invention also relates to a process for the production of an aluminum back electrode of a PERC silicon solar cell and, respectively, to a process for the production of a PERC silicon solar cell including the steps:
(1) providing a silicon wafer having an ARC layer on its front-side and a perforated dielectric passivation layer on its back-side,
(2) applying and drying an aluminum paste in any one of its embodiments described herein on the perforated dielectric passivation layer on the back-side of the silicon wafer, and
(3) firing the dried aluminum paste, whereby the wafer reaches a peak temperature of 700 to 900° C.

In step (1) of the process of the invention a silicon wafer having an ARC layer on its front-side and a perforated dielectric passivation layer on its back-side is provided. The silicon wafer is a mono- or polycrystalline silicon wafer as is conventionally used for the production of silicon solar cells; it has a p-type region, an n-type region and a p-n junction. The silicon wafer has an ARC layer on its front-side and a perforated dielectric passivation layer on its back-side, both layers, for example, of TiOₓ, SiOₓ, TiOₓ/SiOₓ, SiNₓ or, in particular, a dielectric stack of SiNₓ/SiOₓ. Such silicon wafers are well known to the skilled person; for brevity reasons reference is expressly made to the disclosure above. The silicon wafer may already be provided with the conventional front-side metallizations, i.e. with a front-side silver paste as described above. Application of the front-side metallization may be carried out before or after the aluminum back electrode is finished.

In step (2) of the process of the invention an aluminum paste in any one of its embodiments described herein is applied on the perforated dielectric passivation layer on the back-side of the silicon wafer, i.e. covering the dielectric as well as the perforations.

The aluminum paste is applied to a dry film thickness of, for example, 15 to 60 μm. Typically, it is applied as a single layer. The method of aluminum paste application may be printing, for example, silicone pad printing or, in an embodiment, screen printing.

The application viscosity of the aluminum paste may be 20 to 200 Pa·s when it is measured at a spindle speed of 10 rpm and 25° C. by a utility cup using a Brookfield HBT viscometer and #14 spindle.

After application, the aluminum paste is dried, for example, for a period of 1 to 100 minutes with the silicon wafer reaching a peak temperature in the range of 100 to 300° C. Drying can be carried out making use of, for example, belt, rotary or stationary driers, in particular, IR (infrared) belt driers.

In step (3) of the process of the invention the dried aluminum paste is fired to form an aluminum back electrode. The firing of step (3) may be performed, for example, for a period of 1 to 5 minutes with the silicon wafer reaching a peak temperature in the range of 700 to 900° C. The firing can be carried out making use of, for example, single or multi-zone belt furnaces, in particular, multi-zone IR belt furnaces. The firing may happen in an inert gas atmosphere or in the presence of oxygen, for example, in the presence of air. During firing the organic substance including non-volatile organic material and the organic portion not evaporated during the drying may be removed, i.e. burned and/or carbonized, in particular, burned. The organic substance removed during firing includes organic solvent(s), optionally present organic polymer(s), optionally present organic additive(s) and the organic moieties of optionally present metal-organic compounds. There is a further process taking place during firing, namely sintering of the glass frit with the particulate aluminum. During firing the aluminum paste does not fire through the back-side perforated passivation layer, but it makes local contacts with the silicon substrate back surface at the places of the perforations in the passivation layer and forms local BSF contacts, i.e. the passivation layer survives at least essentially between the fired aluminum paste and the silicon substrate.

Firing may be performed as so-called cofiring together with other metal pastes that have been applied to the PERC solar cell silicon wafer, i.e., front-side and/or back-side metal pastes which have been applied to form front-side and/or back-side electrodes on the wafer's surfaces during the firing process. An embodiment includes front-side silver pastes and back-side silver or back-side silver/aluminum pastes. In an embodiment, such back-side silver or back-side silver/aluminum paste is a silver or silver/aluminum paste having no or only poor fire-through capability. A back-side silver or back-side silver/aluminum paste without or with only poor fire-through capability does not etch through the back-side perforated passivation layer during firing; thus it makes only local physical contact with the silicon back-surface of the wafer at the places of the perforations in the passivation layer.

As already mentioned, the aluminum paste of the invention may also be used in the manufacture of aluminum back electrodes of LFC-PERC silicon solar cells or respectively in the manufacture of LFC-PERC silicon solar cells.

Accordingly, the invention relates also to a process for the production of an aluminum back electrode of an LFC-PERC silicon solar cell and, respectively, to a process for the production of an LFC-PERC silicon solar cell including the steps:
(1) providing a silicon wafer having an ARC layer on its front-side and a non-perforated dielectric passivation layer on its back-side,
(2) applying and drying an aluminum paste in any one of its embodiments described herein on the non-perforated dielectric passivation layer on the back-side of the silicon wafer,
(3) firing the dried aluminum paste, whereby the wafer reaches a peak temperature of 700 to 900° C., and
(4) laser firing the fired aluminum layer obtained in step (3) and the dielectric passivation layer underneath the fired aluminum layer to produce perforations in said passivation layer and to form local BSF contacts.

In other words, the process for the production of an aluminum back electrode of a LFC-PERC silicon solar cell deviates from the above mentioned process for the production of an aluminum back electrode of a conventional PERC silicon solar cell in that in process steps (1) and (2) the back-side dielectric passivation layer has no perforations and in that an additional step (4) of laser firing is carried out. Since the back-side dielectric passivation layer has no perforations, a fired aluminum layer but no local BSF contacts are formed in the course of process step (3). In the course of said additional process step (4) the back-side dielectric passivation layer is provided with perforations and the local BSF contacts are formed. The perforations are, for example, 50 to 300 μm in diameter and their number lies in the range of, for example, 100 to 500 per square centimeter. The laser firing creates a temperature above the melting point of aluminum so as to form an aluminum-silicon melt at the perforations resulting in the formation of the local BSF contacts which are in electrical contact with the fired aluminum layer obtained in step (3). As a consequence of the local BSF contacts being in electrical contact with the fired aluminum layer, the latter becomes an aluminum back anode.

### EXAMPLES

### (1) Manufacture of Test Samples

### (i) Example Aluminum Paste

The example aluminum paste comprised 72 wt. % air-atomized aluminum powder (d50=6 μm), 27 wt. % organic vehicle of polymeric resins and organic solvents and 1 wt. % of glass frit. The glass frit composition was 1 wt. % SiO2, 0.5 wt. % Al2O3, 9.5 wt. % B2O3, 13 wt. % ZnO, 3 wt. % BaO and 73 wt. % Bi2O3 and the glass had a softening point temperature (glass transition temperature, determined by differential thermal analysis DTA at a heating rate of 10 K/min) of 430° C.

### (ii) Formation of TLM Samples

A p-type multicrystalline silicon wafer of 80 cm² area and 160 μm thickness with an n-type diffused POCl₃ emitter, having a SiNₓ ARC on the front-side and a non-perforated 100 nm thick SiO₂/SiNₓ rear surface dielectric stack, was screen printed on the back surface with parallel lines of the example aluminum paste. The aluminum paste was patterned at a nominal line width of 100 μm with a line spacing (pitch) of 2.05 mm; the dried film thickness of the aluminum paste was 20 μm.

The printed wafer was then fired in a 6-zone infrared furnace supplied by Despatch. A belt speed of 580 cm/min was used with zone temperatures defined as zone 1=500° C., zone 2=525° C., zone 3=550° C., zone 4=600° C., zone 5=900° C. and the final zone set at 865° C. Using a DataPaq thermal data logger the peak wafer temperature was found to reach 730° C.

The fired wafer was subsequently laser scribed and fractured into 8 mm×42 mm TLM samples, where the parallel aluminum metallization lines did not touch each other. Laser scribing was performed using a 1064nm infrared laser supplied by Optek.

### (iii) Formation of an Adhesion Test Sample

A p-type multicrystalline silicon wafer of 243 cm² area and 160 μm thickness with an n-type diffused POCl₃ emitter, having a SiNₓ ARC on the front-side and a non-perforated SiO₂/SiNₓ rear surface dielectric stack was provided. The example aluminum paste was screen printed full plane and dried. The aluminum paste had a dried layer thickness of 30 μm. The printed and dried wafer was then fired in a 6-zone infrared furnace supplied by Despatch. A belt speed of 580 cm/min was used with zone temperatures defined as zone 1=500° C., zone 2=525° C., zone 3=550° C., zone 4=600° C., zone 5=900° C. and the final zone set at 865° C. Using a DataPaq thermal data logger the peak wafer temperature was found to reach 730° C.

The back surface with the dielectric stack and the fired aluminum metallization was then processed using a 1064 nm wavelength laser to obtain perforations (vias) of 80 μm in diameter with a pitch (spacing) of 500 μm.

### (2) Test Procedures

### (i) TLM Measurement

The TLM samples were measured by placing them into a GP 4-Test Pro instrument available from GP Solar for the purpose of measuring contact resistivity. The measurements were performed at 20° C. with the samples in darkness. The test probes of the apparatus made contact with 6 adjacent fine line aluminum electrodes of the TLM samples, and the contact resistivity (ρc) was recorded.

### (ii) Fired Adhesion

In order to measure the cohesive strength of the aluminum metallization the amount of material removed from the back face of the fired wafer was determined using a peel test. To this end, a transparent layer of adhesive tape (3M Scotch Magic tape grade 810) was firmly applied and subsequently removed by peeling at an angle of 45 degrees. By ratioing the area of residue on the tape to the area of material remaining on the wafer, a qualitative assessment of the adhesion could be made.

The example aluminum paste exhibited the following results:
Adhesion (area % without adhesion loss)=100%, no residue on the tape after the peel test.
The contact resistivity exceeded the upper measurable limit for the GP 4-Test Pro equipment (>364 Ω·cm²).

What is claimed is:

1. An aluminum paste having no or only poor fire-through capability and comprising particulate aluminum, an organic vehicle and at least one lead-free glass frit selected from the group consisting of glass frits containing 0.5 to 15 wt. % SiO₂, 0.3 to 10 wt. % Al₂O₃ and 67 to 75 wt. % Bi₂O₃, wherein the weight percentages are based on the total weight of the glass frit.

2. The aluminum paste of claim 1, wherein the particulate aluminum is present in a proportion of 50 to 80 wt. %, based on total aluminum paste composition.

3. The aluminum paste of claim 1, wherein the organic vehicle content is from 20 to 45 wt. %, based on total aluminum paste composition.

4. The aluminum paste of claim 1, wherein the at least one lead-free glass frit contains also at least one of the following: >0 to 12 wt. % B₂O₃, >0 to 16 wt. % ZnO, >0 to 6 wt. % BaO.

5. The aluminum paste of claim 1, wherein the total content of the at least one lead-free glass frit in the aluminum paste is 0.25 to 8 wt. %.

6. A process for the production of a PERC silicon solar cell comprising the steps:
(1) providing a silicon wafer having an ARC layer on its front-side and a perforated dielectric passivation layer on its back-side,
(2) applying and drying the aluminum paste of claim 1 on the perforated dielectric passivation layer on the back-side of the silicon wafer, and
(3) firing the dried aluminum paste, whereby the wafer reaches a peak temperature of 700 to 900° C.

7. The process of claim 6 for the production of a LFC-PERC silicon solar cell, wherein a non-perforated dielectric passivation layer is used instead of the perforated dielectric passivation layer and wherein the process comprises the additional step:
(4) laser firing the fired aluminum layer and the dielectric passivation layer underneath the fired aluminum layer to produce perforations in said passivation layer and to form local BSF contacts.

8. The process of claim 6, wherein firing is performed as cofiring together with other front-side and/or back-side metal pastes that have been applied to the silicon wafer to form front-side and/or back-side electrodes thereon during firing.

9. The process of claim 8, wherein said other back-side metal paste(s) is/are selected from the group consisting of silver pastes having no or only poor fire-through capability and silver/aluminum pastes having no or only poor fire-through capability.

10. The process of claim 6, wherein the aluminum paste is applied by printing.

11. A PERC silicon solar cell made by the process of claim 6.

12. A PERC silicon solar cell comprising an aluminum back electrode wherein the aluminum back electrode is produced making use of the aluminum paste of claim 1.

13. The PERC silicon solar cell of claim 12, further comprising a silicon wafer.
